(19) United States
(12) Patent Application Publication
(10) Pub. No.: US 2009/0140759 A1
(43) Pub. Date: Jun. 4, 2009

(54) IC socket having contact devices with low impedance

(75) Inventors: Shih-Wei Hsiao, Tu-cheng (TW); Chun-Fu Lin, Tu-Cheng (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 12/315,398

(22) Filed: Dec. 3, 2008

(30) Foreign Application Priority Data
Dec. 3, 2007 (TW) 96220464

(51) Int. Cl. G01R 31/02

(52) U.S. Cl. 324/755; 439/66

(57) ABSTRACT

A contact device (5) for interconnecting two electronic devices comprises: an upper contact pin (51) having a contacting portion (511) extending upward for connecting one electronic device, and a mating portion (513) of a substantial plate-type structure extending downward and defining a planar mating surface (5132); an lower contact pin (52) having a contacting portion (521) extending downward for connecting the other electronic device, and a mating portion (523) of a substantial plate-type structure extending upward and defining a planar mating surface (5232); a coil spring (53) fitted between the upper contact pin and lower contact pin. The mating portions (513, 523) of the upper and the lower contact pins are substantial coplanar with each other, and the mating surfaces (5132, 5232) of the upper and the lower contact pins contact with each other.

### BACKGROUND OF THE INVENTION

1. Field of the invention

The present invention relates to an IC socket for testing an IC package, and particularly to an IC socket employs a number of contact devices, each of which includes two pieces of mated contact pins.

2. Description of related art

U.S. Pat. No. 7,025,602 issued to “Dong Weon Hwang” on Apr. 11, 2006, discloses a conventional IC socket adapted to interconnect an IC package and a printed circuit board (PCB). Referring to FIG. 5 and FIG. 6 of this patent, the IC socket includes a socket body with a number of contact devices received therein, and a cover pivotally coupled to the socket body. The contact device comprises an upper terminal for connecting the IC package, a lower terminal for connecting the conductive pad on the PCB, and a coil spring enclosing and engaging the upper and the lower terminals. The upper and the lower terminals have same configurations, and each of them has a contacting portion extending out of the socket body and a mating portion for mating with the other of the upper and the lower terminals. The mating portion comprises a pair of arms extending in a same direction and defines a slot therebetween. Each of the arms is formed with a hook at a free end thereof. A transverse bridging portion is formed to interconnect the two arms. The upper and the lower terminals are arranged substantially perpendicular to each other, in which the hooks of any of the upper and the lower terminals are movably received in the slot of the other of the upper and the lower terminals, so that each of the upper and the lower terminals is able to slide in a vertical direction with respect to the other one.

However, this conventional contact device has a complicated structure and thereby not easy to be manufactured. Further, the contacting area of the mating portion is relative small, which results in a relative high impedance of the contact device.

In view of the above, a new IC socket with improved contact devices which overcome the above-mentioned disadvantages is desired.

### SUMMARY OF THE INVENTION

Accordingly, an object of the present invention is to provide an IC socket having improved contact devices.

To achieve the above second object, an IC socket made in accordance with a preferred embodiment of the present invention is provided for receiving an IC package. The IC socket comprises an upper receiving plate defining a plurality of upper receiving holes, a lower receiving plate defining a plurality of lower receiving holes. Each lower receiving hole is corresponding to one of the upper receiving holes to define a receiving passageway. A plurality of contact devices are respectively received in the passageways. Each contact device includes an upper contact pin, a lower contact pin coupled to the upper contact pin, and a coil spring fitted between the upper contact pin and the lower contact pin. Each of the upper contact pin and the lower contact pin has a contacting portion capable of extending out of the upper receiving plate or the lower receiving plate, and a mating portion of a substantial plate-type structure defining a planar mating surface. The mating portions of the upper contact pin and the lower contact pin are in parallel arrangement, with mating surfaces thereof abutting against with each other. A receiving frame is located on the upper receiving plate for accommodating the IC package.

Other objects, advantages and novel features of the invention will become more apparent from the following detailed description when taken in conjunction with the accompanying drawings, in which:

### BRIEF DESCRIPTION OF THE DRAWINGS

FIG. 1 is an assembled, perspective view of the IC socket in accordance with the preferred embodiment of the present invention;

FIG. 2 is an exploded, perspective view of the IC socket in FIG. 1. Contact devices of the IC socket are not illustrated in FIG. 2;

FIG. 3 is a sectional view showing a number of contact devices received within an upper receiving plate and a lower receiving plate;

FIG. 4 is a perspective view of the contact device, which includes an upper contact pin, a lower contact pin and a coil spring fitted therebetween;

FIG. 5 is an exploded, perspective view of the contact device in FIG. 4;

FIG. 6 is a side view showing the upper contact pin and the lower contact pin mating with each other; and

FIG. 7 is an assembly, perspective view of the contact device received within the upper receiving plate and the lower receiving plate.

### DETAILED DESCRIPTION OF THE INVENTION

Reference will now be made to the drawings to describe the present invention in detail.

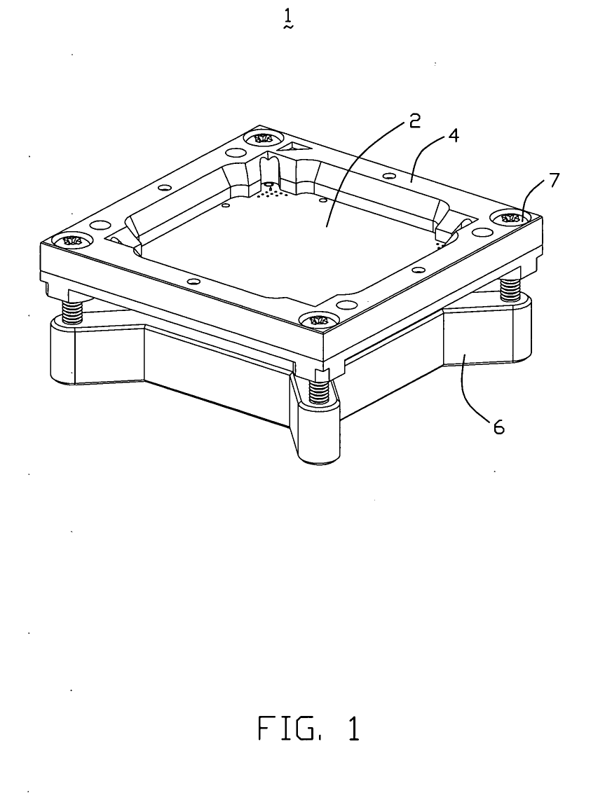

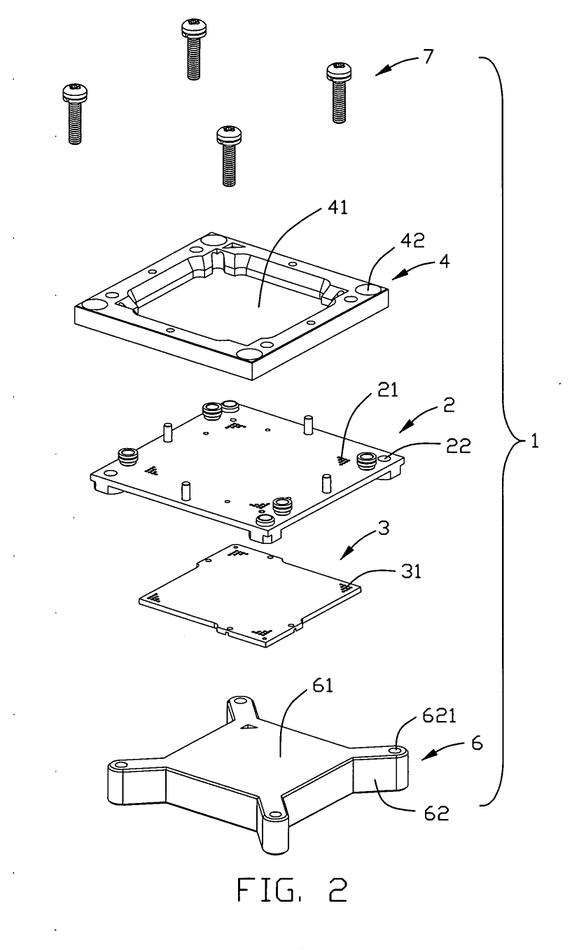

Referring to FIG. 1 to FIG. 3, an IC socket 1 for interconnecting an IC package (not shown) and a printed circuit board (not shown), according to a preferred embodiment of the present invention, includes a upper receiving plate 2, a lower receiving plate 3 stacked below the upper receiving plate 2, and a receiving frame 4 located upon the upper receiving plate 2. A plurality of contact devices 5 are received between the upper and the lower receiving plates 2, 3. Further, a back plate 6 is provided below the printed circuit board to retain the IC socket 1 by using a plurality of screws 7.

The upper receiving plate 2 defines a plurality of upper receiving holes 21, each of which further includes a first hole 211 extending through a top surface of the upper receiving plate 2 and a second hole 212 extending through a bottom surface of the upper receiving plate 2. A shoulder 213 is therefore formed at a junction point due to the different dimensions of the first and the second holes 211, 212. Four mounting holes 22 adapted to mount the screws 7, are respectively formed at the corners of the upper receiving plate 2.

The lower receiving plate 3, which has a similar structure to the upper receiving plate 2, defines a plurality of lower receiving holes 31, each of which further includes a third hole 311 extending through a bottom surface of the lower receiving plate 3 and a forth hole 312 extending through a top surface of the lower receiving plate 3. A shoulder 313 is therefore formed at a junction point of the third and the forth holes 311, 312 due to the different dimensions of the third and the forth holes 311, 312. Each of the lower receiving holes 31 is corresponding to one of the upper receiving holes 21 to together define a receiving passageway (not labeled) for receiving the contact device 5.

The receiving frame 4 defines an opening 41 for accommodating the IC package, and four mounting holes 42 in the vicinity of the corners for the screws 7.

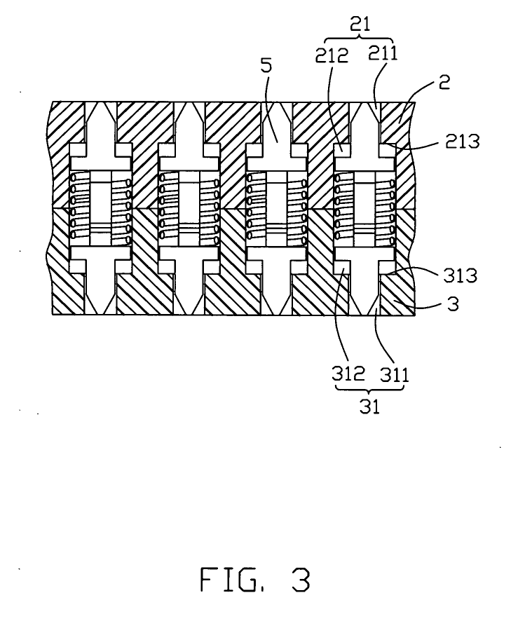

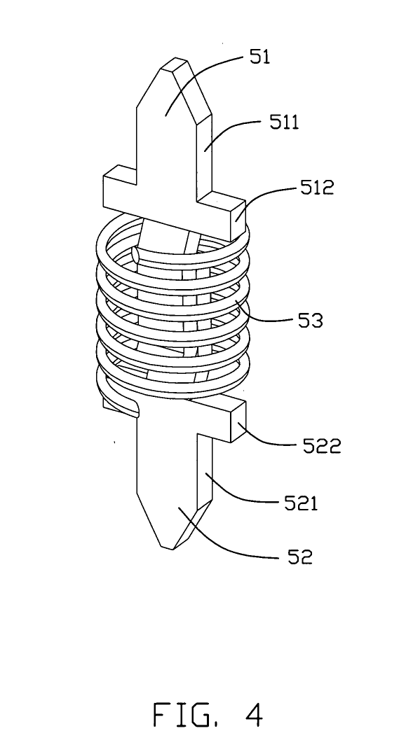

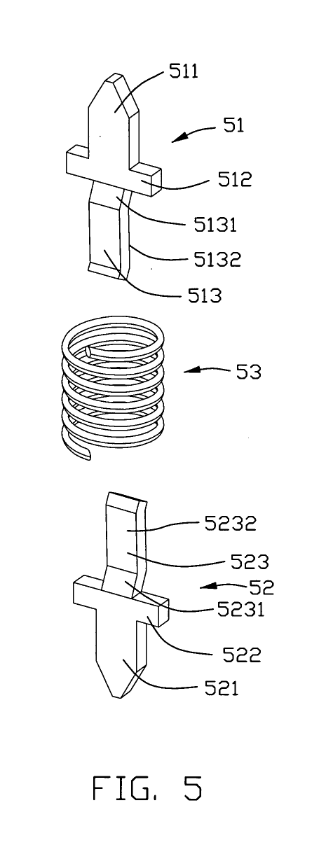

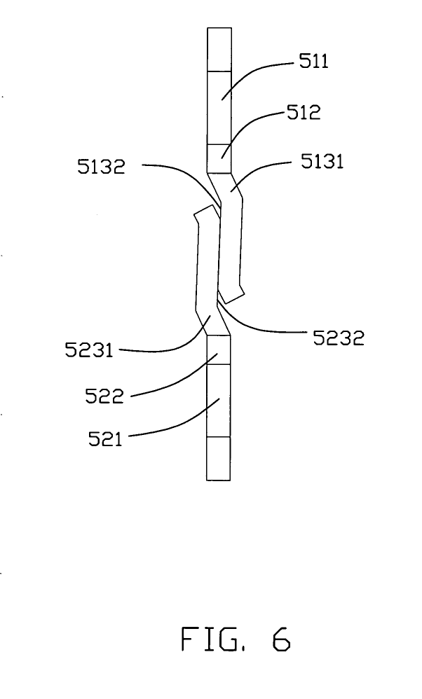

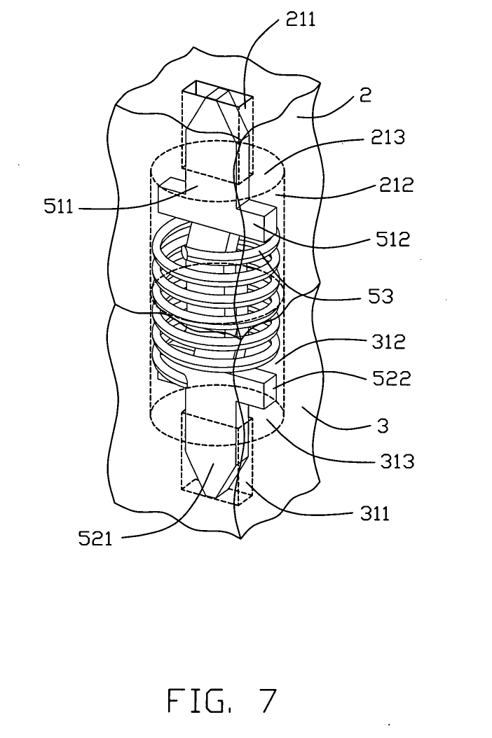

Referring to FIG. 3 to FIG. 7, the contact device 5 includes a upper contact pin 51, a lower contact pin 52, and a coil spring 53 fitted between the upper and the lower contact pins 51, 52. The upper and the lower contact pins 51, 52 are punched from a metal plate and have same configurations. Each of the upper and the lower contact pins 51, 52 has a contacting portion 511, 521 capable of extending out of the upper or the lower receiving plate 2, 3, and a mating portion 513, 523 of a substantial plate-type structure defining a planar mating surface 5132, 5232. The mating portions 513, 523 are in parallel arrangement, with the mating surfaces 5132, 5232 abutting against with each other. A support protrusion 512, 522 is formed to extend between the contacting portion 511, 521 and the mating portion 513, 523, to abut against the coil spring 53 and thereby keeps the coil spring 53 positioned between the support protrusions 512, 522 of the upper and the lower contact pins 51, 52. The mating portion 513, 523 is formed with a bending portion 5131, 5231 at one end that connecting to the support protrusion 512, 522, so that the contacting portion 511, 521 is offset with the mating portion 513, 523 in a vertical direction. The free end of the mating portion 513, 523 is bended obliquely to facilitate the engagement between the mating portions 513, 523 of the upper and the lower contact pins 51, 52. When the mating surfaces 5132, 5232 contact with each other, the contacting portions 511, 521 are in align with each other in the vertical direction.

The contacting portions 511, 521 extend out of the upper receiving plate 2 or the lower receiving plate 3 in an initial position. When the IC socket 1 is mounted to a printed circuit board and then an IC package applies a load to the contact devices 5, the upper and the lower contact pins 51, 52 relatively move toward each other and the mating surfaces 5132, 5232 relatively slide on each other. Simultaneously, the coil spring 53 compresses to generate an elastic force. When the IC package is released, the upper and the lower contact pins 51, 52 move away from each other due to the elastic force of the coil spring 53.

As the engagement between the upper and the lower contact pins 51, 52 is achieved by surface contact between the mating portions 513, 523 which have large contact areas for the contacting surfaces, the impedance of the contact device 5 is therefore reduced so as to maintain a fine electrical performance. Besides, the contact device 5 of the present invention has a relative simple structure and therefore easy to be manufactured.

While a preferred embodiment in accordance with the present invention has been shown and described, equivalent modifications and changes known to persons skilled in the art according to the spirit of the present invention are considered within the scope of the present invention as defined in the appended claims.

What is claimed is:

1. An IC socket for receiving an IC package comprising:
an upper receiving plate defining a plurality of upper receiving holes;
a lower receiving plate defining a plurality of lower receiving holes, each of which is corresponding to one of said upper receiving holes to define a receiving passageway;
a plurality of contact devices respectively received in the passageways, each contact device including an upper contact pin, a lower contact pin coupled to the upper contact pin, and a coil spring fitted between the upper contact pin and the lower contact pin, each of the upper contact pin and the lower contact pin having a contacting portion capable of extending out of the upper receiving plate or the lower receiving plate, and a mating portion of a substantial plate-type structure defining a planar mating surface, the mating portions of the upper contact pin and the lower contact pin being in parallel arrangement, with mating surfaces thereof abutting against with each other; and
a receiving frame located on the upper receiving plate for accommodating the IC package.

2. The IC socket as claimed in claim 1, wherein a support protrusion extending between the contacting portion and the mating portion is formed to abut against the coil spring and thereby keeps the coil spring positioned between the support protrusions of the upper and the lower contact pins.

3. The IC socket as claimed in claim 2, wherein the mating portion is formed with a bending portion at one end that connecting to the support protrusion, so that the contacting portion is offset with the mating portion in a vertical direction.

4. The IC socket as claimed in claim 3, wherein the free end of the mating portion is bended obliquely to facilitate the engagement between the mating portions of the upper and the lower contact pins.

5. The IC socket as claimed in claim 4, wherein the contacting portions of the upper and the lower contact pins are in align with each other in the vertical direction.

6. The IC socket as claimed in claim 1, wherein at least one of the upper receiving hole and the lower receiving hole comprises two parts with different dimensions and therefore a shoulder is formed at a junction point.

7. A contact device for interconnecting two electronic devices comprising:
an upper contact pin having a contacting portion extending upward for connecting one electronic device, and a mating portion of a substantial plate-type structure extending downward and defining a planar mating surface;
an lower contact pin having a contacting portion extending downward for connecting the other electronic device, and a mating portion of a substantial plate-type structure extending upward and defining a planar mating surface; and
a coil spring fitted between the upper contact pin and lower contact pin;
wherein the mating portions of the upper and the lower contact pins are substantial coplanar with each other, and the mating surfaces of the upper and the lower contact pins contact with each other.

8. The contact device as claimed in claim 7, wherein a support protrusion extending between the contacting portion and the mating portion is formed to abut against the coil spring and thereby keeps the coil spring positioned between the support protrusions of the upper and the lower contact pins.

9. The contact device as claimed in claim 8, wherein the mating portion is formed with a bending portion at one end that connecting to the support protrusion, so that the contacting portion is offset with the mating portion in a vertical direction.

10. The IC socket as claimed in claim 9, wherein the free end of the mating portion is bended obliquely to facilitate the engagement between the mating portions of the upper and the lower contact pins.

11. The IC socket as claimed in claim 10, wherein the contacting portions of the upper and lower contact pins are in align with each other in the vertical direction.

12. An IC socket comprising:
a first insulative housing and a second insulative housing back to back stacked with each other with two interior faces of said two housings abutting against each other,
each of said two housing defines a hole with a large section adjacent to the interior face, and a small section adjacent to an exterior face opposite to said interior face under condition of the holes in the first housing being essentially aligned with the holes in the second housing, respectively; and
a plurality of contacts disposed in the corresponding holes in each of said housings, each of said contacts defining an outer segment moveable within the corresponding small section, and an inner segment moveable within the corresponding large section; wherein
the inner segment of the contact in the hole of the first housing engages the inner segment of the corresponding contact in the hole of the second housing under condition that said two holes are essentially aligned with each other and that a spring is disposed in said two holes for urging the corresponding two contacts therein away from each other.

13. The IC socket as claimed in claim 12, wherein the large section is columnar while the small section is rectangular.

14. The IC socket as claimed in claim 12, wherein said inner segment is larger than the outer segment.

15. The IC socket as claimed in claim 12, wherein a step structure is formed between the small section and the corresponding large section, and the inner segment defines a protrusion abutting against said step structure due to urge of said spring.

16. The IC socket as claimed in claim 12, wherein the inner segment defines an offset section relative to the corresponding outer segment for engagement with another offset section of the corresponding inner segment, both of which are respectively disposed in the corresponding holes which are essentially aligned with each other.
